(19) United States
(12) Patent Application Publication
(10) Pub. No.: US 2012/0247953 A1
(43) Pub. Date: Oct. 4, 2012

(54) FILM-COATING SYSTEM

(76) Inventors: CHIEN-MIN WENG, Tao-Yuan (TW); Shih-Liang Chou, Tao-Yuan (TW); Tzu-Wen Chu, Tao-Yuan (TW); Fu-Jen Wang, Tao-Yuan (TW); Feng-Shiang Yao, Tao-Yuan (TW)

(21) Appl. No.: 13/073,337

(22) Filed: Mar. 28, 2011

(51) Int. Cl. C23C 16/52; C23C 14/34; C23C 16/02; C23C 16/455; B05C 11/00; B05C 13/00

(52) U.S. Cl. 204/298.26; 118/702

(57) ABSTRACT

The invention relates to a film coating system. The system includes serially arranged working zones including a rough vacuum feeding section, a high vacuum feeding section, an optical layer coating zone, a pretreatment zone, a transparent conductive layer coating zone and a pressure balanced exhausting zone. The system further includes a conveyor device for carrying a substrate which has been provided on its periphery with an ink frame layer and for delivering the substrate to the respective working zones, and a controlling device that controls the times for the substrate to be retained in the respective working zones based upon a time interval between the entry of two successive conveyor devices into the rough vacuum feeding section. The invention ensures a smooth operation of the production line, and the transparent conductive film coated thereby does not easily exfoliate and exhibits the advantageous properties of high optical performance and low surface resistance.

### BACKGROUND OF THE INVENTION

1. Field of the Invention

The present invention relates to a continuous film coating system that has the advantages of saving manpower and enhancing the productivity and quality of the thin films produced thereby, and more particularly, to a film coating system suitable for manufacturing a touch panel structure.

2. Description of the Prior Art

Vacuum sputtering deposition is an important aspect of vacuum coating technology, the concept of which involves dispersing a noble gas, such as argon, between two metal plates differing in electric potential under a high vacuum environment and allowing electrons to collide with argon molecules to form a plasma, so that the argon ions present in the plasma impact the surface of the cathode plate (on which a target material is usually disposed) upon being accelerated by the electric field applied, and the impact causes some molecules to fly away from the target material and arrive at the anode plate (on which a substrate is normally disposed), thereby depositing the target molecules on the substrate to form a thin film. The aforesaid thin-film deposition process is carried out by having molecules to move in a linear motion, it is more environmentally friendly as compared to a traditional chemical plating process. Moreover, the thin films made by sputtering deposition show good adhesion to various types of substrates and are uniform in texture and flat in appearance. Therefore, the vacuum sputtering deposition process is very suitable for coating thin films of various materials on a planar substrate having a broad surface area.

A conventional touch panel is usually formed on the outermost cover substrate thereof with a layer of indium tin oxide (ITO) as its conductance. Integrating this combination with the display panel constitutes a complete touch screen. The ITO sensing layer is employed to establish a uniform electrostatic field across the glass substrate. Touch control is accomplished by sensing a slight change in the electric current caused by a human touch, such as by a finger touch.

The conventional film-coating process known in the art generally comprises the steps of subjecting a substrate to a heat treatment at an elevated temperature of more than 250° C. for 10˜30 minutes, and then subjecting the substrate to an ITO sputtering treatment at the elevated temperature in a sputtering chamber, followed by quenching the sputtered substrate to form a crystallized ITO film on the substrate. However, the substrate produced by the conventional process described above will be remarkably weakened in its strength since it is rapidly heated up at high temperature and subjected to the sputtering treatment before being cooled down rapidly, not to mention that the sputtering temperature is too high for plastic base material to handle. As a consequence, the application scope of the prior art process is seriously compromised due to the reason that it is inapplicable to the materials other than glass (such as plastic base material).

Furthermore, the cover substrate of a touch panel is normally printed on its periphery with a black icon or artwork layer to shield the circuits. The icon or artwork layer, if experiencing a high sputtering temperature, would undergo a property change, causing the icon or artwork layer to peel off of from the substrate or the ITO film layer.

### SUMMARY OF THE INVENTION

An object of the invention is to provide a film coating system that has the advantages of saving manpower and enhancing the productivity and quality of the thin films produced thereby, and more particularly, to a film coating system suitable for manufacturing a touch panel structure.

In order to achieve the object described above, the film coating system according to the invention comprises serially arranged working zones, including a rough vacuum feeding section, a high vacuum feeding section, an optical layer coating zone, a pretreatment zone, a transparent conductive layer coating zone and a pressure balanced exhausting zone. The system further includes a conveyor device for carrying a substrate which has been provided on its periphery with an ink frame layer and for delivering the substrate to the respective working zones, and a controlling device that controls the times for the substrate to be retained in the respective working zones based upon a time interval between the entry of two successive conveyor devices into the rough vacuum section. The invention ensures a smooth operation of the production line, and the transparent conductive layer coated thereby does not easily exfoliate but exhibits the advantageous properties of high optical performance and low surface resistance.

### BRIEF DESCRIPTION OF THE DRAWINGS

The above and other objects, features and effects of the invention will become apparent with reference to the following description of the preferred embodiments taken in conjunction with the accompanying drawings, in which:

FIG. 1 is a schematic diagram illustrating a film coating system according to the first preferred embodiment of the invention;

FIG. 2 is a perspective view showing the conveyor device of the inventive system, on which a number of substrates are carried;

FIGS. 3(A) and 3(B) are schematic film structure diagrams showing a substrate sputter deposited with thin films by using the system according to the invention; and

FIG. 4 is a perspective view of the gas gate valve according to the invention.

### DETAILED DESCRIPTION OF THE PREFERRED EMBODIMENTS

The present invention relates to a film coating system, and more particularly, to a system for sequentially coating an optical layer and a transparent conductive layer on a pre-treated substrate. The product produced by the inventive system is suitable for use in a touch panel. The invention significantly reduces the probability of generation of etching marks on the transparent conductive film in the subsequent processing stage by installment of the optical layer. Further, the inventive system is capable of carrying out a film coating process in a continuous and rapid manner and, hence, is advantageous in saving manpower and enhancing the productivity and quality of the thin films produced thereby.

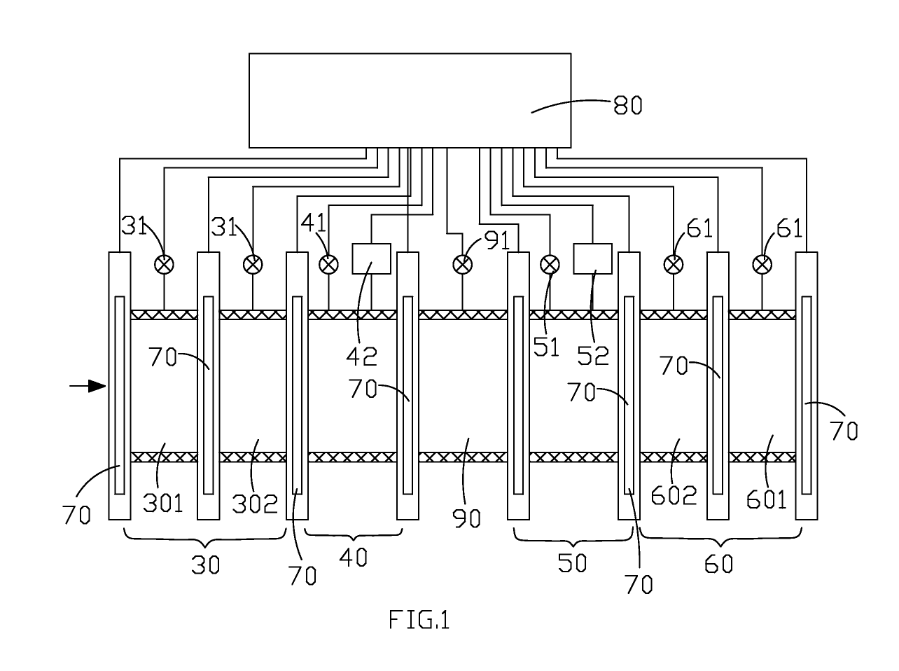

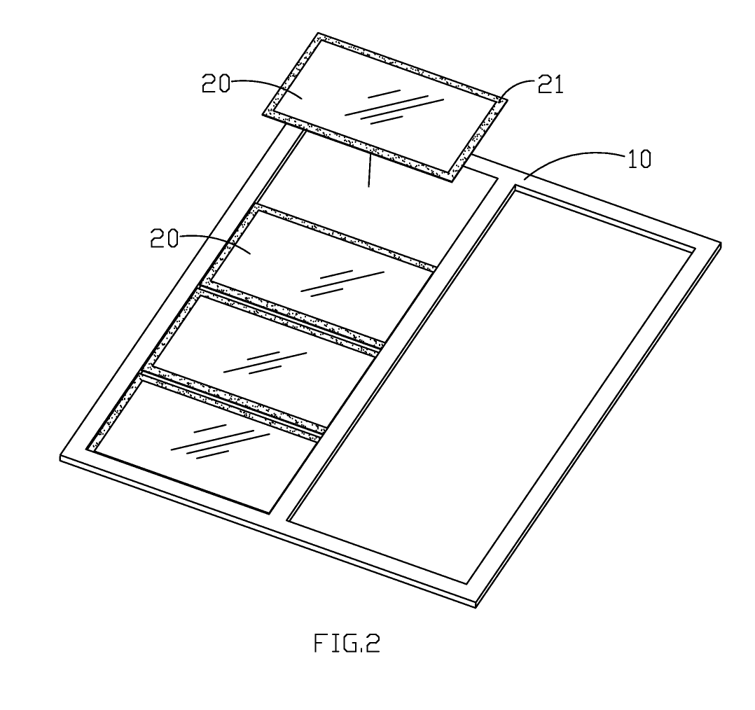

Now referring to FIGS. 1 and 2, the film coating system according to the invention comprises the following constituting elements.

A conveyor device 10 (which may by way of example be a trolley) is used for carrying and delivering a substrate 20 to respective working zones, wherein the substrate 20 is provided on its periphery with an ink frame layer 21 which may by way of example be formed through an ink printing process.

A pressure balanced feeding zone 30 is provided, which is further equipped with at least one pressure-controlling member 31 to render the pressure balanced feeding zone 30 to have an interior pressure substantially the same as that of the immediate downstream working zone. According to this embodiment, the pressure balanced feeding zone 30 includes a rough vacuum section 301 and a high vacuum section 302 arranged in series, with both of the rough vacuum section 301 and the high vacuum section 302 being provided with a pressure-controlling member 31, respectively.

An optical layer coating zone 40 is disposed downstream of the pressure balanced feeding zone 30 and provided with a pressure-controlling member 41 and a temperature-controlling member 42. Preferably, the optical layer coating zone 40 is maintained at a low temperature (less than 250° C.) and under a high vacuum state.

A pretreatment zone 90 is provided, which is further equipped with a pressure-controlling member 91. Preferably, the pretreatment zone 90 is first evacuated to a high vacuum state and then fed with a gas, such as oxygen (with a gas mass flow rate of 10˜50 SCCM) and argon (with a gas mass flow rate of 10˜50 SCCM), and supplied with electric power to generate an ion source (wherein the voltage level of the electric power is controlled in a range between 500˜2000V and preferably between 800˜1200V). The ion source is then utilized to treat a surface of the substrate 20.

A transparent conductive layer coating zone 50 is disposed downstream of the optical layer coating zone 40 and provided with a pressure-controlling member 51 and a temperature-controlling member 52. Preferably, the transparent conductive layer coating zone 50 is maintained at a low temperature (less than 250° C.) and under a high vacuum state.

A pressure balanced exhausting zone 60 is disposed downstream of the transparent conductive layer coating zone 50 and equipped with at least one pressure-controlling member 61 to render the pressure balanced exhausting zone 60 to have an interior pressure substantially the same as ambient pressure. Preferably, the pressure balanced exhausting zone 60 includes a high vacuum section 602 and a rough vacuum section 601 arranged in series, with both of the rough vacuum section 601 and the high vacuum section 602 being provided with a pressure-controlling member 61, respectively.

A plurality of valve members 70 are disposed in the respective working zones and serve to operatively seal off the respective working zones.

A controlling device 80 is provided for controlling the conveyor device 10, the controlling members and the valve members 70 described above.

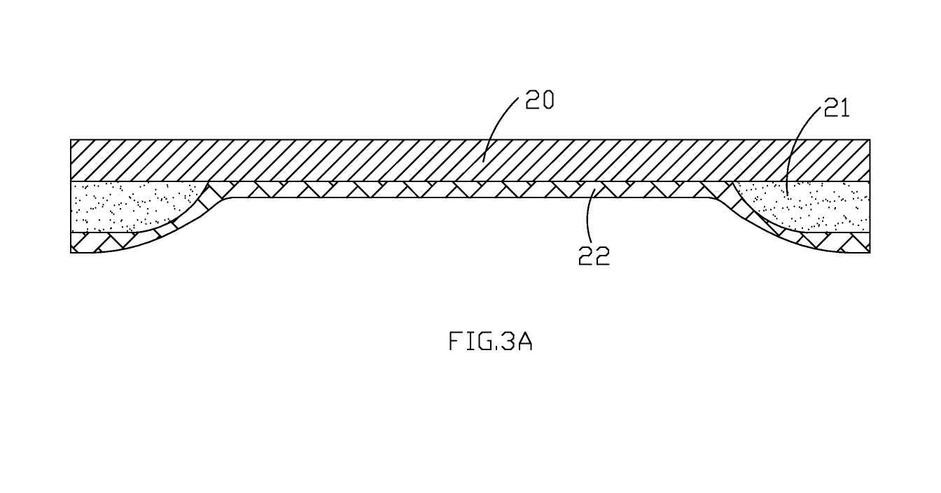

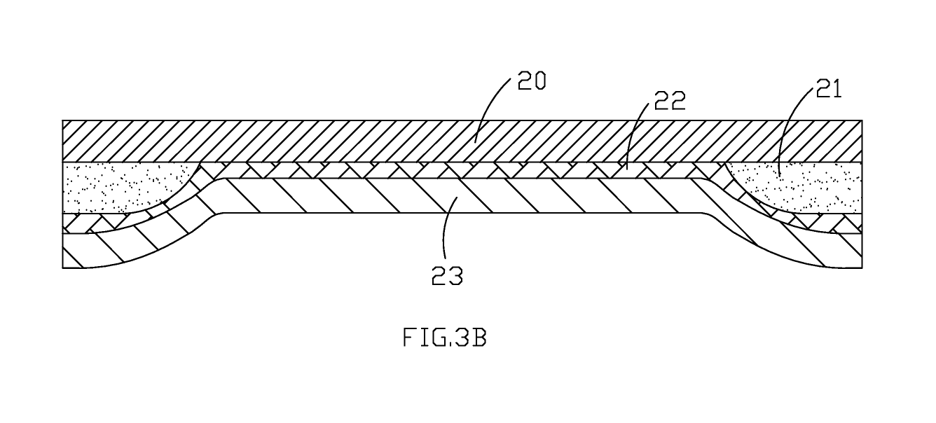

During the use of the inventive film coating system, the conveyor device is activated to deliver the substrate to respective working zones. The substrate is first delivered to the rough vacuum section 301 of the pressure balanced feeding zone. After the corresponding valve members 70 are closed and seal off the rough vacuum section 301, the section 301 is evacuated to a rough vacuum pressure (about 10⁻² torr) by means of the pressure-controlling member 31. When the interior pressure of the rough vacuum section 301 reaches the rough vacuum pressure, the valve member 70 coupling between the rough vacuum section 301 and the high vacuum section 302 is opened up to allow entry of the substrate into the high vacuum section 302. After the valve member 70 is closed off, the high vacuum section 302 continues to be evacuated to reach a high vacuum pressure (about 10⁻⁶ torr). When the pressure of the high vacuum section 302 reaches the rough vacuum pressure, the valve member 70 coupling between the high vacuum section 302 and the optical layer coating zone 40 is opened up to allow entry of the substrate into the optical layer coating zone 40 where the substrate is subjected to a sputtering process. A target material and a heat source are properly placed within the optical layer coating zone 40 according to the knowledge of those skilled in the art, so that the substrate 20 is sputter deposited with an optical layer 22 as shown in FIG. 3(A). The high vacuum state is maintained throughout the sputtering deposition process, thereby ensuring that the optical layer thus coated is excellent in quality. Meanwhile, since the substrate is pre-printed with an ink frame layer 21, the working temperature used in the optical layer coating zone 40 should be kept at a low temperature (less than 250° C.), so as to prevent the ink frame layer 21 from undergoing a change in property. When the sputtering deposition process is performed, it is preferably that the substrate is moved back and forth within the optical layer coating zone 40 by the conveyer device, as a means to increase the uniformity of the deposited film layer.

Afterwards, the substrate 20 is transferred to the pretreatment zone 90 where the ion source is employed to treat a surface of the substrate 20. Such a pretreatment will not only achieve an effect of surface cleaning, but also render the conductive film to be coated on substrate 20 in the follow-up stage to exhibit a reduced surface resistance, an improved conductivity and a higher crystalline level. The substrate 20 is next transferred to the transparent conductive layer coating zone 50 where the substrate is subjected to an additional sputtering process, by which the substrate 20 is sputter deposited over the optical film 22 with a transparent conductive layer 23 as shown in FIG. 3(B). After completion of the sputtering process, the substrate 20 is delivered to the high vacuum section 602 of the pressure balanced exhausting zone 60 and then to the rough vacuum section 601 and finally exhausted from the system as a finished product. The product may be deposited with a single layer or multiple layers of the optical films 22, depending on the desired optical performance or specification requirements.

The controlling device 80 determines and controls the times for respective substrates to be retained in the respective working zones, based upon the time interval between the entry of two successive conveyor devices into the pressure balanced feeding zone (ΔT), so as to protect the respective substrates from collision with one another and ensure the smooth operation of the production line. That is, assuming that the time intervals for a given substrate to be retained in the rough vacuum feeding section, high vacuum feeding section, the optical layer coating zone, the pretreatment zone and the transparent conductive layer coating zone are defined to be T1, T2, T3, T4 and T5, respectively, then ΔT>T1>T2>T3≧T4>T5 and ΔT<T1+T2. Preferred examples are given in the Table below to illustrate the time intervals between the entry of two successive conveyor devices (ΔT) and the retaining times for individual substrates in the respective working zones.

| Time interval | | | | | |
|---|---|---|---|---|---|
| (ΔT)(second) | T1 (s) | T2 (s) | T3 (s) | T4 (s) | T5 (s) |
| 600 | 480 | 360 | 240 | 240 | 5 |
| 480 | 360 | 240 | 200 | 160 | 5 |
| 360 | 300 | 180 | 80 | 50 | 5 |
| 300 | 180 | 120 | 50 | 20 | 5 |
| 260 | 180 | 120 | 50 | 20 | 5 |
| 240 | 180 | 120 | 50 | 20 | 5 |

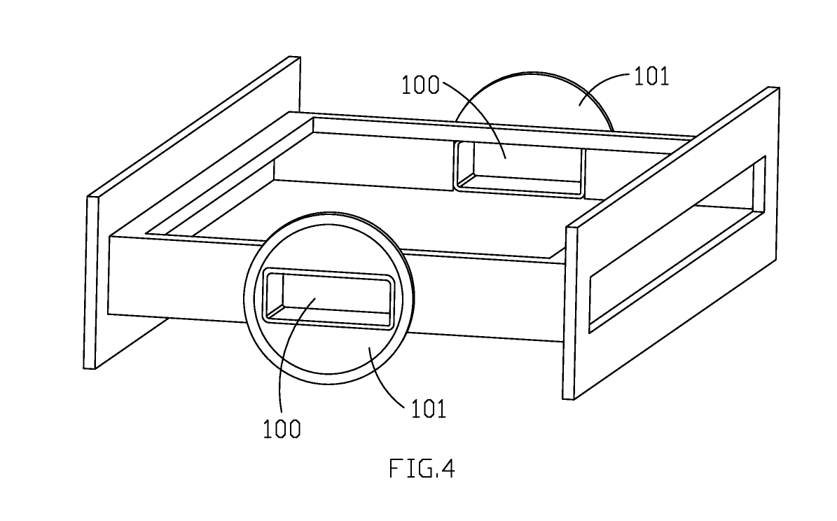

Preferably, the respective pressure-controlling members are provided with an adapter 101 coupling to a gas gate valve 100 provided in the corresponding working zone, so that the pressure-controlling members are able to control the flow rate of the gas introduced into or evacuated from the corresponding working zones. As shown in FIG. 4, the gas gate valve 100 is configured to have a cross-sectional area greater than that of its prior art counterpart. Preferably, the cross-sectional area of the gas gate valve 100 is greater than one-third of the cross section area of the adapter 101, so that as compared to the conventional systems, the invention allows a greater amount of gas flowing through the gas gate valve 100 and the adapter 101 in a given unit of time and, therefore, significantly reduces the time needed for achieving the desired gas pressure.

It is noted that the invention has the following advantages:

1. The invention provides a system that allows a continuous processing regime, in which a substrate is deposited with an optical layer and then with a transparent conductive layer via a single production line. The product thus obtained is particularly suitable for use in a projective capacitive touch panel. The installment of the optical film will significantly reduces the probability of generation of etching marks on the transparent conductive layer in the subsequent processing stage, thereby enhancing the overall optical performance.
2. The optical layer coating zone and the transparent conductive layer coating film are both maintained at a relatively low temperature (less than 250° C.), at which a substrate made of, for example, glass or plastic material will no longer have to face the problem of undergoing a property change. Furthermore, the resultant transparent conductive layer is highly durable and is characterized by having the desired surface resistance value and thickness. The invention is provided for coating thin films on a semi-finished substrate which has already been coated with an ink frame layer, and the transparent conductive layer coated by the invention will neither undergo a property change nor easily exfoliate.
3. The substrate is subjected to a pretreatment before being sputter deposited with a transparent conductive layer. This pretreatment will not only achieve an effect of surface cleaning, but also render the conductive layer to be coated on substrate in the follow-up stage to exhibit a reduced surface resistance, an improved conductivity and a higher crystalline level.
4. According to the invention, the times for an individual substrate to be retained in the respective working zones are controlled based upon the time interval between the entry of two successive conveyor devices into the pressure balanced feeding zone (ΔT), so that the substrate are protected from collision with other substrates and the smooth operation of the production line is ensured.

While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit of the invention and the scope thereof as defined in the appended claims.

What is claimed is:

1. A film coating system comprising: at least one conveyor device and a controlling device, in combination with serially arranged working zones comprising a rough vacuum feeding section, a high vacuum feeding section, an optical layer coating zone maintained at a low temperature of less than 250° C., a pretreatment zone, a transparent conductive layer coating zone maintained at a low temperature of less than 250° C. and a pressure balanced exhausting zone;
wherein the conveyor device is used for carrying a substrate which has been provided on its periphery with an ink frame layer and for delivering the substrate to the respective working zones, and wherein any two of the adjacent working zones are connected via a valve member; and
wherein the controlling device controls the times for the substrate to be retained in the respective working zones, based upon a time interval between the entry of two successive conveyor devices into the rough vacuum feeding section (ΔT), and wherein assuming that the time intervals for the substrate to be retained in the rough vacuum feeding section, high vacuum feeding section, the optical layer coating zone, the pretreatment zone and the transparent conductive layer coating zone are defined to be T1, T2, T3, T4 and T5, respectively, then ΔT>T1>T2>T3≧T4>T5 and ΔT<T1+T2.

2. The film coating system according to claim 1, wherein the respective working zones are provided with a pressure-controlling member.

3. The film coating system according to claim 2, wherein the respective pressure-controlling members are provided with an adapter coupling to a gas gate valve formed in the corresponding working zone, and wherein the gas gate valve is configured to have a cross-sectional area greater than one-third of across section area of the adapter.

4. The film coating system according to claim 1, wherein the pretreatment zone is fed with a gas and supplied with electric power to generate an ion source for treating a surface of the substrate.

5. The film coating system according to claim 4, wherein the electric power supplied to the pretreatment zone has a voltage level ranging between 500˜2000V.

6. The film coating system according to claim 5, wherein the voltage level ranges between 800˜1200V.

7. The film coating system according to claim 4, wherein the gas fed into the pretreatment zone comprises oxygen introduced with a gas mass flow rate of 10˜50 SCCM and argon introduced with a gas mass flow rate of 10˜50 SCCM.

8. The film coating system according to claim 1, wherein the conveyer device moves the substrate carried thereon back and forth within the optical layer coating zone, when the substrate is subjected to sputtering.

9. The layer coating system according to claim 1, wherein the pressure balanced exhausting zone includes a high vacuum exhausting section and a rough vacuum exhausting section arranged in series.

10. The film coating system according to claim 1, wherein the time interval ΔT is set from 240 to 600 seconds, T1 is set from 180 to 480 seconds, T2 is set from 120 to 360 seconds, T3 is set from 50 to 240 seconds and T4 is set from 20 to 240 seconds.
